(19) United States
(12) Patent Application Publication
(10) Pub. No.: US 2025/0266842 A1
(43) Pub. Date: Aug. 21, 2025

(54) SIGNAL GENERATION CIRCUIT, FREQUENCY LOCKED LOOP CIRCUIT AND PHASE LOCKED LOOP SYSTEM

(71) Applicant: NOVATEK Microelectronics Corp., Hsinchu (TW)

(72) Inventors: Chung-Chih HUNG, Hsinchu City (TW); Tzu-Ting YANG, Kaohsiung City (TW); Chia-Wei LIN, Hualien County (TW); Meng-Ting WU, Taipei City (TW); Chin-Tung CHAN, New Taipei City (TW)

(21) Appl. No.: 18/772,298

(22) Filed: Jul. 15, 2024

(30) Foreign Application Priority Data
Feb. 20, 2024 (TW) 113106037

(51) Int. Cl. H03L 7/093; H03F 1/32; H03F 3/45; H03L 7/099

(52) U.S. Cl. CPC H03L 7/093; H03F 1/3211; H03F 3/45475; H03L 7/099; H03F 2203/45674

(57) ABSTRACT

A signal generation circuit comprising a first chopper, an operational transconductance amplifier, a second chopper and a ripple reduction loop circuit. The operational transconductance amplifier is coupled to receive a differential input signal, and the differential input signal is processed into an output signal at an output node by the operational transconductance amplifier and the second chopper. The ripple reduction loop circuit is coupled between the output node and a compensation node of the operational transconductance amplifier. The ripple reduction loop circuit comprises a third chopper and an operational amplifier. The third chopper is configured to convert a ripple in the output signal into a direct current offset signal. The operational amplifier is configured to convert the direct current offset signal into a compensation signal. The compensation signal is configured to input to the compensation node of the current mirror circuit.

### CROSS-REFERENCE TO RELATED APPLICATION

This application claims priority to Taiwan Application Serial Number 113106037, filed Feb. 20, 2024, which is herein incorporated by reference in its entirety.

### BACKGROUND

### Technical Field

The present disclosure relates to a signal generation method, in particular a signal generation circuit, frequency locked loop circuit, phase locked loop system.

### Description of Related Art

In various electronic products, clock generator is an indispensable component. In order to prevent the clock signal from being interfered by noise, the clock generator is configured with a frequency locked loop circuit (FLL). However, since noise may still be generated inside the frequency locking circuit, the frequency locking circuit must be adjusted to ensure the accuracy and stability of the clock signal.

### SUMMARY

One aspect of the present disclosure is a signal generation circuit, comprising a first chopper, an operational transconductance amplifier, a second chopper and a ripple reduction loop circuit. The operational transconductance amplifier comprises a differential input circuit, a current mirror circuit and an amplifier circuit. The differential input circuit is coupled to the first chopper to receive a differential input signal. The second chopper is coupled to the operational transconductance amplifier. The differential input signal is processed into an output signal at an output node by the current mirror circuit, the amplifier circuit and the second chopper. The ripple reduction loop circuit is coupled between the output node and a compensation node of the current mirror circuit. The ripple reduction loop circuit comprises a third chopper and an operational amplifier. The third chopper is configured to convert a ripple in the output signal into a direct current offset signal. The operational amplifier is coupled to the third chopper and configured to convert the direct current offset signal into a compensation signal. The compensation signal is configured to input to the compensation node of the current mirror circuit.

Another aspect of the present disclosure is a frequency locked loop circuit, comprising a signal generation circuit and a voltage controlled oscillator. The signal generation circuit comprising a first chopper, an operational transconductance amplifier, a second chopper and a ripple reduction loop circuit. The operational transconductance amplifier is coupled to the first chopper to receive a differential input signal. The second chopper is coupled to the operational transconductance amplifier. The differential input signal is processed into an output signal at an output node by the operational transconductance amplifier and the second chopper. The ripple reduction loop circuit is coupled to the output node to receive the output signal, and comprises a third chopper and an operational amplifier. The third chopper is configured to convert a ripple in the output signal into a direct current offset signal, and the operational amplifier is configured to convert the direct current offset signal into a compensation signal to compensate for an offset voltage in the operational transconductance amplifier. The voltage controlled oscillator is coupled to the signal generation circuit, and is configured to generate a reference clock signal according to the output signal.

Another aspect of the present disclosure is a phase locked loop system, comprising a signal generation circuit, a voltage controlled oscillator and a phase locked loop circuit. The signal generation circuit comprises a first chopper, an operational transconductance amplifier, a second chopper and a ripple reduction loop circuit. The operational transconductance amplifier is coupled to the first chopper to receive a differential input signal. The second chopper is coupled to the operational transconductance amplifier. The differential input signal is processed into an output signal at an output node by the operational transconductance amplifier and the second chopper. The ripple reduction loop circuit is coupled to the output node to receive the output signal, and comprises a third chopper and an operational amplifier. The third chopper is configured to convert a ripple in the output signal into a direct current offset signal, and the operational amplifier is configured to convert the direct current offset signal into a compensation signal to compensate for an offset voltage in the operational transconductance amplifier. The voltage controlled oscillator is coupled to the signal generation circuit, and is configured to generate a reference clock signal according to the output signal. The phase locked loop circuit is coupled to the voltage controlled oscillator to receive the reference clock signal, and is configured to output a output clock signal. The phase locked loop circuit is configured to generate a feedback signal according to the output clock signal to adjust a phase of the output clock signal.

It is to be understood that both the foregoing general description and the following detailed description are by examples, and are intended to provide further explanation of the disclosure as claimed.

### BRIEF DESCRIPTION OF THE DRAWINGS

The present disclosure can be more fully understood by reading the following detailed description of the embodiment, with reference made to the accompanying drawings as follows:

FIG. 1 is a schematic diagram of a phase locked loop system in some embodiments of the present disclosure.

FIG. 2 is a schematic diagram of a frequency locked loop circuit in some embodiments of the present disclosure.

FIG. 3 is a schematic diagram of a signal generation circuit in some embodiments of the present disclosure.

FIG. 4 is a schematic diagram of a signal generation circuit in some embodiments of the present disclosure.

FIG. 5 is a schematic diagram of a phase locked loop circuit in some embodiments of the present disclosure.

### DETAILED DESCRIPTION

For the embodiment below is described in detail with the accompanying drawings, embodiments are not provided to limit the scope of the present disclosure. Moreover, the operation of the described structure is not for limiting the order of implementation. Any device with equivalent functions that is produced from a structure formed by a recombination of elements is all covered by the scope of the present disclosure. Drawings are for the purpose of illustration only, and not plotted in accordance with the original size.

It will be understood that when an element is referred to as being “connected to” or “coupled to”, it can be directly connected or coupled to the other element or intervening elements may be present. In contrast, when an element to another element is referred to as being “directly connected” or “directly coupled,” there are no intervening elements present. As used herein, the term “and/or” includes an associated listed items or any and all combinations of more.

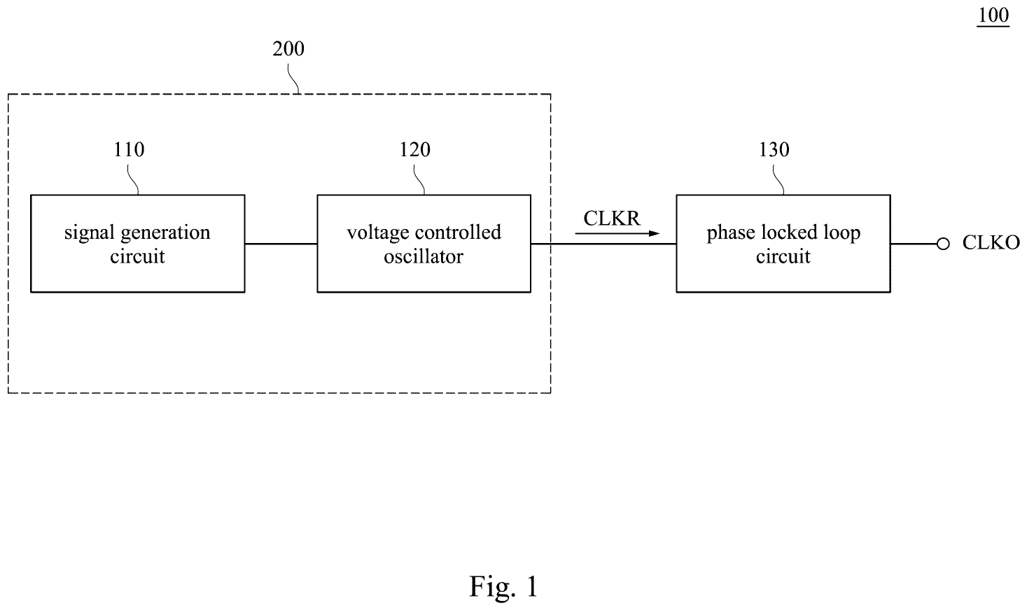

The present disclosure relates to a signal generation circuit, a frequency locked loop circuit and a phase locked loop system. As shown in FIG. 1, in one embodiment, the phase locked loop system 100 includes a signal generation circuit 110, a voltage controlled oscillator 120 and a phase locked loop circuit 130. The signal generation circuit 110 and the voltage controlled oscillator 120 are configured to a frequency locked loop circuit 200 (FLL). The frequency locked loop circuit 200 is configured to generate a reference clock signal CLKR. The phase locked loop circuit 130 is coupled to the voltage controlled oscillator 120, and is configured to generate an output clock signal CLKO. The phase locked loop circuit 130 generates a feedback signal according to the output clock signal CLKO (e.g., feedback the output clock signal CLKO to the input terminal), so as to adjust the phase of the output clock signal CLKO to achieve the purpose of fixing the signal phase.

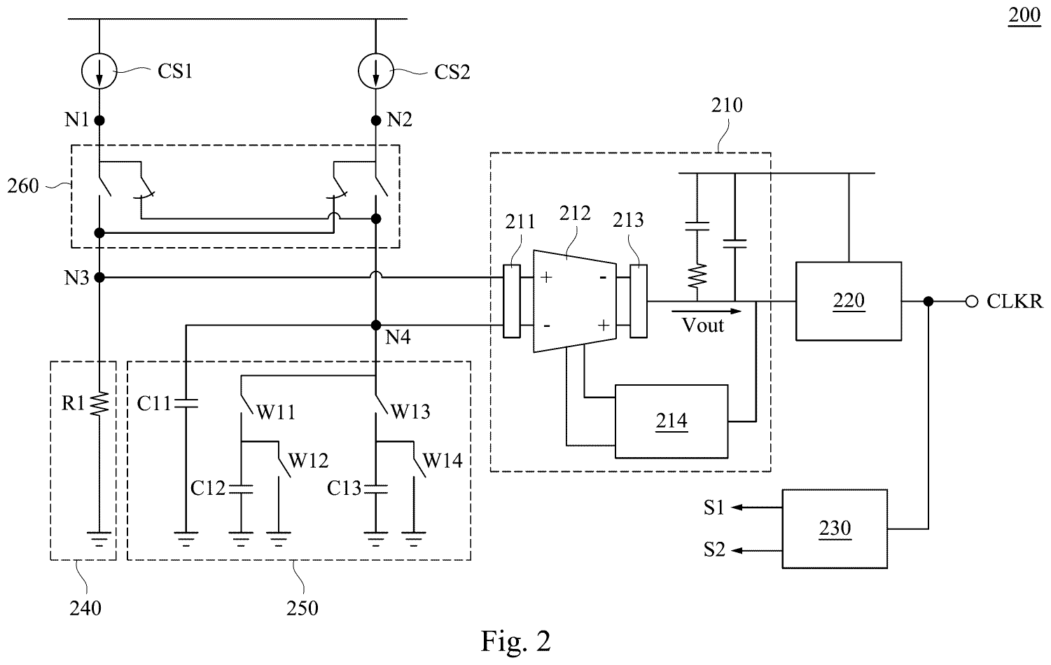

FIG. 2 is a schematic diagram of a frequency locked loop circuit 200 in some embodiments of the present disclosure. The frequency locked loop circuit 200 includes a signal generation circuit 210 and a voltage controlled oscillator 220. The frequency locked loop circuit 200 obtains a input current by power nodes N1, N2. The signal generation circuit 210 includes a first input node N3 (e.g., positive node) and a second input node N4 (e.g., negative node). The signal generation circuit 210 is configured to output a reference clock signal CLKR according to a voltage difference between the first input node N3 and the second input node N4.

In one embodiment, the signal generation circuit 210 receives input signal by multiple current sources CS1/CS2, a first impedance circuit 240 and a second impedance circuit 250. As shown in FIG. 2, the first input node N3 is coupled to the current source CS1 and the first impedance circuit 240, and the second input node N4 is coupled to the current source CS2 and the second impedance circuit 250. In one embodiment, the first impedance circuit 240 includes at least one impedance element R1. The second impedance circuit 250 includes at least one switching element W11-W14 and at least one capacitor C11-C13. The switching elements W11-W14 are respectively controlled by different control signals (e.g., the switching elements W11, W12 are alternately conducted, and the switching elements W13, W14 are alternately conducted), so as to change the overall impedance of the second impedance circuit 250 by charging and discharging of the capacitors C12-C13.

In other words, the impedance value of the second impedance circuit 250 is variable. Through a difference between the impedance value of the second impedance circuit 250 and the impedance value of the first impedance circuit 240, a voltage difference between the first input node N3 and the second input node N4 will be generated. Therefore, the signals received by the first input node N3 and the second input node N4 can be regarded as a kind of differential input signal. The circuit structure of the impedance circuit 240/250 is not limited to that shown in FIG. 2.

In one embodiment, the first input node N3 and the second input node N4 are coupled to the impedance circuit 240/250, and are coupled to power node N1/N2 through a switching circuit 260. In other words, the switching circuit 260 is coupled to the power node N1/N2, and is further coupled to the first input node N3 and the second input node N4 of the signal generation circuit 210. Through internal switches, the switching circuit 260 is configured to periodically change the position where the current source CS1/CS2 is connected to the signal generation circuit 210. Specifically, the switching circuit 260 periodically connects the power node N1 of the current source CS1 to one of the first input node N3 and the second input node N4, and periodically connects the power node N2 of the current source CS2 to the other one of the first input node N3 and the second input node N4. Accordingly, jitter generated by noise of the current source C1/CS2 in the reference clock signal CLKR will be reduced.

The signal generation circuit 210 includes a chopper 211, an operational transconductance amplifier 212, a chopper 213 and a ripple reduction loop circuit 214. The operational transconductance amplifier 212 is coupled to the choppers 211 and 213, and filters noise in signal by the choppers 211 and 213. The chopper 211 is coupled to the input terminal of the signal generation circuit 210 (i.e., the first input node N3 and the second input node N4), and is configured to exchange the received signals (differential input signal), so as to filter low-frequency noise. Similarly, the operational transconductance amplifier 212 convert the input signal into current, the chopper 213 is configured to exchange output signals of the operational transconductance amplifier 212 again, thereby reducing low-frequency noise and forming an output signal Vout. Therefore, the differential input signal is processed into an output signal at an output node by the chopper 211, the operational transconductance amplifier 212, the chopper 213 and the ripple reduction loop circuit 214.

Since circuit components in the operational transconductance amplifier 212 will have mismatch problems, an offset voltage will be formed in the operational transconductance amplifier 212. This offset voltage cannot be filtered by a single chopper 213, and will form a ripple in the output signal Vout. In the frequency domain analysis, a spur will be formed, causing signal instability. Therefore, the present disclosure utilizes the ripple reduction loop circuit 214 as a feedback path to eliminate the influence of offset voltage.

The ripple reduction loop circuit 214 is coupled to the output terminal of the operational transconductance amplifier 212 and compensation node(s) inside the operational transconductance amplifier 212 (compensation node will be described in detail in subsequent paragraphs). The ripple reduction loop circuit 214 is configured to receive the output signal Vout, and includes at least one chopper and an operational transconductance amplifier (not shown in FIG. 2, it will be shown in subsequent drawings). The chopper and the operational transconductance amplifier are coupled to each other, the ripple reduction loop circuit 214 converts ripple in the output signal Vout into a direct current offset signal (a DC offset) by the chopper, then generates at least one compensation signal according to the processed output signal Vout (including the direct current offset signal), and transmits the compensation signal back to the operational transconductance amplifier 212. The compensation signal is configured to input to the compensation node(s) in the operational transconductance amplifier 212, so as to compensate the error effect of the operational transconductance amplifier 212 due to the offset voltage.

The voltage controlled oscillator 220 (VCO) is coupled to the signal generation circuit 210, is configured to generates the reference clock signal CLKR with a fixed frequency according to the output signal Vout. Since those skilled in the art can understand the circuit structure and operation of the voltage controlled oscillator, it will not be described here.

Accordingly, by using the chopper of the ripple reduction loop circuit 214 to eliminate the ripple on the output signal Vout, and generating the compensation signal to correct the error effect of the operational transconductance amplifier 212 due to the offset voltage, the stability of the reference clock signal CLKR output by the frequency locked loop circuit 200 will be ensured.

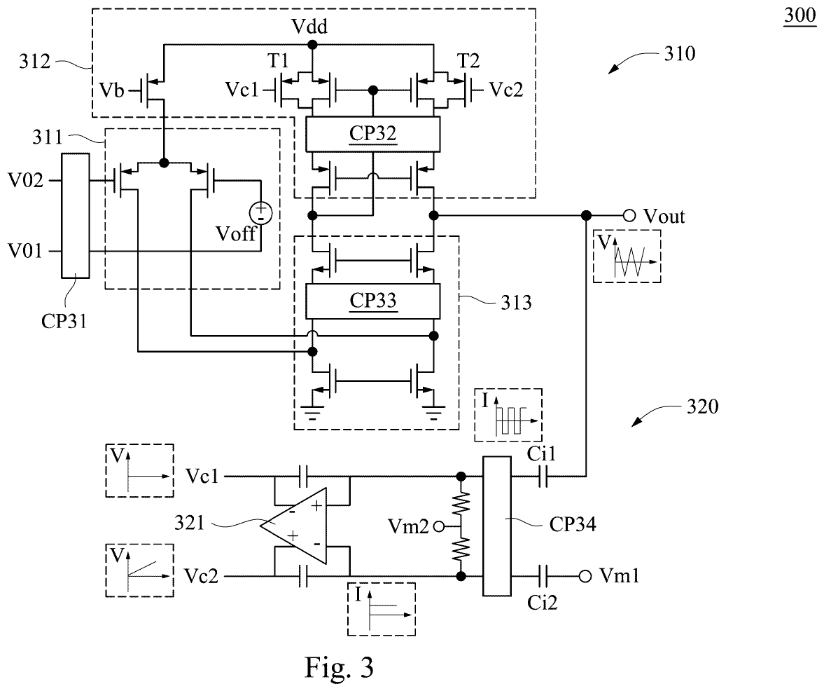

FIG. 3 is a schematic diagram of a signal generation circuit 300 in some embodiments of the present disclosure. In this embodiment, the signal generation circuit 300 includes choppers CP31/CP32/CP33, an operational transconductance amplifier 310 and a ripple reduction loop circuit 320. In FIG. 3, the chopper CP31 corresponds to the chopper 211 in FIG. 2. The chopper CP32/CP33 can be applied as the chopper 213 in FIG. 2, and is configured to reduce the low-frequency noise in the signal, and generate the output signal Vout.

The chopper CP31 is configured to receive signals V01-V02 of two input terminals of the signal generation circuit 300 as the differential input includes a differential input circuit 311, a current mirror circuit 312 and an amplifier circuit 313. The differential input circuit 311 is coupled to the chopper CP31 to receive the differential input signal.

The current mirror circuit 312 is configured to generate current according to a supply voltage Vdd and the control signal Vb. The amplifier circuit 313 (can be a transconductance amplifier circuit) generate the output signal Vout at output terminal according to current provided by the differential input signal and the current mirror circuit 312. In one embodiment, the operational transconductance amplifier 310 includes a cascode amplifier circuit. The choppers CP32, CP33 and CP31 are coupled to the operational transconductance amplifier 310, so as to filter noise generated by the internal circuit components of the operational transconductance amplifier 310. In other words, the differential input signal generates the output signal Vout by the differential input circuit 311, the current mirror circuit 312, the amplifier circuit 313 and the choppers CP31/CP32/CP33.

In one embodiment, the current mirror circuit 312 of the operational transconductance amplifier 310 further includes compensation transistors T1, T2. Two current mirror transistors of the current mirror circuit 312 are respectively connected in parallel with compensation transistors T1, T2. The control terminals (e.g., gate terminal) of the compensation transistors T1, T2 as two compensation nodes to respectively receive different compensation signals.

As shown in FIG. 3, since transistors in the operational transconductance amplifier 310 will have mismatch problems, an offset voltage Voff will be generated. The offset voltage Voff may form anywhere in the operational transconductance amplifier 310, and the position of offset voltage Voff in FIG. 3 is for illustration only. The offset voltage Voff will form a ripple in the output signal Vout, such as a triangular wave shown in FIG. 3.

The ripple reduction loop circuit 320 is coupled between the output node and the compensation node of the operational transconductance amplifier 310, so as to be a feedback path, and is configured to generate compensation signal. The ripple reduction loop circuit 320 includes a chopper CP34 and an operational amplifier 321. The chopper CP34 is configured to receive the output signal Vout including ripple output by the operational transconductance amplifier 310. In one embodiment, the chopper CP34 receives the output signal Vout including ripple through multiple filter capacitors Ci1/Ci2 and the reference voltage Vm1, and is configured to detect the ripple signal in the output signal Vout. FIG. 3 indicates electrical characteristic waveforms of each node of the ripple reduction loop circuit 320 (voltage V or current I as shown in the figure). The waveform at the filter capacitor Ci1 is a current signal provided by the filter capacitor Ci1 to the chopper CP34. Then, by the processing of the chopper CP34, the ripple will be converted into a direct current offset signal (a DC Offset, as shown in FIG. 3, a DC voltage waveform at the output terminal of the chopper CP34).

The operational amplifier 321 is coupled to the chopper CP34, and receives the direct current offset signal (DC offset) processed by the chopper CP34, and convert the direct current offset signal into the compensation signal, so as to input to the compensation nodes of the operational transconductance amplifier 310. As shown in FIG. 3, in one embodiment, two output terminals of the chopper CP34 respectively output different compensation signals Vc1, Vc2 (e.g., as a differential signal). The compensation signals Vc1, Vc2 are respectively input to two compensation nodes of the operational transconductance amplifier 310 (i.e., the control terminals of the compensation transistors T1, T2). Accordingly, it will be able to compensate the spur in the operational transconductance amplifier 310 caused by the offset voltage Voff or offset current.

In addition, in one embodiment, the output terminal of the chopper CP34 may generate a bias voltage Vm2 by a voltage divider circuit. The bias voltage Vm2 is provided to the operational amplifier 321 as a bias power. Since those skilled in the art can understand the working principle of chopper, it will not be described here.

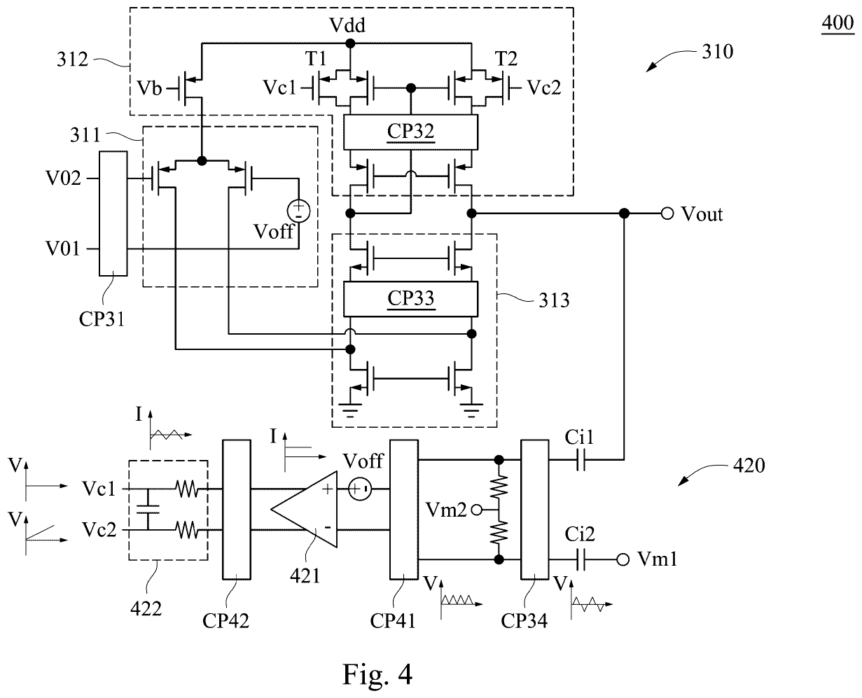

FIG. 4 is a schematic diagram of a signal generation circuit 400 in some embodiments of the present disclosure. In FIG. 4 the similar components associated with the embodiment of FIG. 3 are labeled with the same numerals for ease of understanding. The specific principle of the similar component has been explained in detail in the previous paragraphs, and unless it has a cooperative relationship with the components of FIG. 4, it is not repeated here. In this embodiment, the signal generation circuit 300 includes choppers CP31/CP32/CP33, an operational transconductance amplifier 310 and a ripple reduction loop circuit 420. Choppers CP31/CP32/CP33 and the operational transconductance amplifier 310 are the same as the embodiment shown in FIG. 3, so it will not be described again here.

As shown in FIG. 4, although ripple of the output signal Vout can be eliminated by chopper CP34 in the ripple reduction loop circuit 420, the ripple reduction loop circuit 420 also has an operational amplifier. Therefore, the ripple reduction loop circuit 420 itself may also have an offset voltage (Voff) and be affected.

In this embodiment, the ripple reduction loop circuit 420 includes choppers CP34/CP41/CP42 and an operational amplifier 421. Same as the previous embodiments, the chopper CP34 can receive the output signal Vout including ripple through multiple filter capacitors Ci1/Ci2. FIG. 4 shows electrical characteristic waveforms of each node in the ripple reduction loop circuit 420 (such as voltage V or current I). The waveform shown at filter capacitors Ci1/Ci2 is a voltage signal provided by the filter capacitors Ci1/Ci2 to the chopper CP34. The chopper CP41 is coupled between the chopper CP33 and the operational amplifier 421. The chopper CP42 is coupled between the output terminal of the operational amplifier 421 and the compensation nodes of the current mirror circuit 312. In other words, the operational amplifier 421 is coupled between the choppers CP41 and CP42. Accordingly, noise caused by the offset voltage Voff of the operational amplifier 421 will be filtered out by the choppers CP41 and CP42.

In one embodiment, the ripple reduction loop circuit 420 further includes a filter circuit 422. The filter circuit 422 is coupled to two output terminals of the chopper CP42 to generate a first compensation signal Vc1 and a second compensation signal Vc2. The first compensation signal Vc1 and the second compensation signal Vc2 is provided to control terminals of the compensation transistors T1, T2 in the current mirror circuit 312. As shown in FIG. 4, the first compensation signal Vc1 and the second compensation signal Vc2 have different voltage levels. For example, the compensation signals Vol and Vc2 can be used as a differential signal, and the voltage of the two compensation signals changes with time. In other words, there is a voltage difference between the first compensation signal Vc1 and the second compensation signal Vc2, and this voltage difference is configured to compensate noise caused by the offset voltage Voff of the operational transconductance amplifier 310.

The signal generation circuit 300/400 in FIG. 3 and FIG. 4 mentioned above can be applied to the signal generation circuit 210 shown in FIG. 2. As shown in FIG. 2, in one embodiment, the frequency locked loop circuit 200 further includes a shunt circuit 230. The shunt circuit 230 is coupled to the voltage controlled oscillator 220, and is configured to generate multiple control signals S1, S2 according to the reference clock signal CLKR. The control signals S1, S2 are provided to switching elements W11-W14 in the second impedance circuit 250. In other words, the second impedance circuit 250 is turned on or turn off according to the reference clock signal CLKR, so as to adjust the impedance value of the second impedance circuit 250.

In some embodiments, the shunt circuit 230 has a non-overlapping circuit, and is configured to ensure that the control signals S1 and S2 are not at the enable level or disable level at the same time.

As shown in FIG. 1, in some embodiments of the present disclosure, the reference clock signal CLKR generated by the frequency locked loop circuit is provided to the phase locked loop circuit 130, so as to generate the output clock signal CLKO. Accordingly, the reference clock signal CLKR must be stable, otherwise the output clock signal CLKO will be affected.

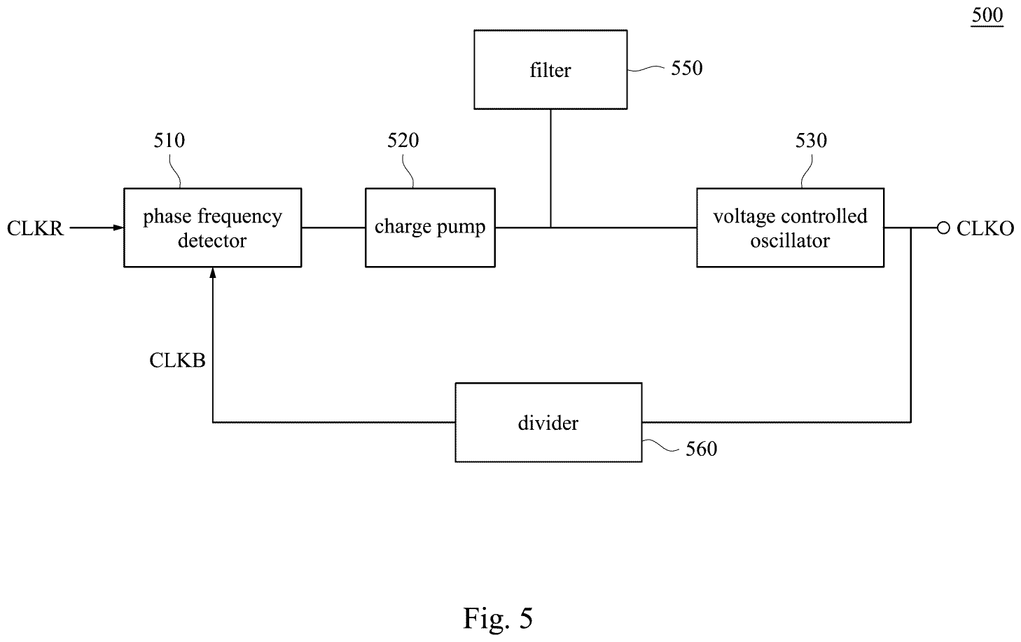

FIG. 5 is a schematic diagram of a phase locked loop circuit 500 in some embodiments of the present disclosure. The phase locked loop circuit 500 can be applied to the phase locked loop circuit 130 shown in FIG. 1. The phase locked loop circuit 500 includes a phase frequency detector (PFD) 510, a charge pump 520, a voltage controlled oscillator (VCO) 530, a filter 550 and a divider 560. The filter is coupled between the charge pump 520 and the voltage controlled oscillator 530, and the divider 560 is coupled between the voltage controlled oscillator 530 and the phase frequency detector 510.

The phase locked loop circuit 500 is configured to receive the reference clock signal CLKR, and is configured to generate the output clock signal CLKO. In addition, the phase locked loop circuit 500 uses the output clock signal CLKO as a feedback signal CLKB by the divider 560, and adjusts the phase of the output clock signal CLKO according to the feedback signal CLKB and the reference clock signal CLKR. Accordingly, the frequency of the output clock signal CLKO will tend to a target frequency, and will be finally locked to the target frequency.

The elements, method steps, or technical features in the foregoing embodiments may be combined with each other, and are not limited to the order of the specification description or the order of the drawings in the present disclosure.

It will be apparent to those skilled in the art that various modifications and variations can be made to the structure of the present disclosure without departing from the scope or spirit of the present disclosure. In view of the foregoing, it is intended that the present disclosure cover modifications and variations of this present disclosure provided they fall within the scope of the following claims.

What is claimed is:

1. A signal generation circuit, comprising:
a first chopper;
an operational transconductance amplifier comprising a differential input circuit, a current mirror circuit and an amplifier circuit, wherein the differential input circuit is coupled to the first chopper to receive a differential input signal;
a second chopper coupled to the operational transconductance amplifier, wherein the differential input signal is processed into an output signal at an output node by the current mirror circuit, the amplifier circuit and the second chopper; and
a ripple reduction loop circuit coupled between the output node and a compensation node of the current mirror circuit, and comprising:
a third chopper configured to convert a ripple in the output signal into a direct current offset signal; and
an operational amplifier coupled to the third chopper and configured to convert the direct current offset signal into a compensation signal, wherein the compensation signal is configured to input to the compensation node of the current mirror circuit.

2. The signal generation circuit of claim 1, wherein the ripple reduction loop circuit further comprises:
a fourth chopper coupled to between the third chopper and the operational amplifier; and
a fifth chopper coupled to the operational amplifier to receive the compensation signal.

3. The signal generation circuit of claim 2, wherein the compensation node comprises a first compensation node and a second compensation node to receive a first compensation signal and a second compensation signal of the compensation signal, and the ripple reduction loop circuit further comprises:
a filter circuit coupled to two output terminals of the fifth chopper, and configured to generate the first compensation signal and the second compensation signal, wherein a voltage difference is between the first compensation signal and the second compensation signal.

4. The signal generation circuit of claim 3, wherein the operational transconductance amplifier further comprises two compensation transistors, the two compensation transistors are respectively connected in parallel with two current mirror transistors in the current mirror circuit, and a plurality of control terminals of the two compensation transistors receive the first compensation signal and the second compensation signal.

5. The signal generation circuit of claim 1, wherein the third chopper receives the output signal by a filter capacitor.

6. A frequency locked loop circuit, comprising:
a signal generation circuit comprising:
a first chopper;
an operational transconductance amplifier coupled to the first chopper to receive a differential input signal;
a second chopper coupled to the operational transconductance amplifier, wherein the differential input signal is processed into an output signal at an output node by the operational transconductance amplifier and the second chopper; and
a ripple reduction loop circuit coupled to the output node to receive the output signal, and comprising a third chopper and an operational amplifier, wherein the third chopper is configured to convert a ripple in the output signal into a direct current offset signal, and the operational amplifier is configured to convert the direct current offset signal into a compensation signal to compensate for an offset voltage in the operational transconductance amplifier; and
a voltage controlled oscillator coupled to the signal generation circuit, and configured to generate a reference clock signal according to the output signal.

7. The frequency locked loop circuit of claim 6, wherein the operational transconductance amplifier comprises a current mirror circuit and an amplifier circuit, the differential input signal is processed into the output signal at the output node by the current mirror circuit, the amplifier circuit and the second chopper, and the compensation signal is configured to input to a compensation node of the current mirror circuit.

8. The frequency locked loop circuit of claim 7, wherein the ripple reduction loop circuit further comprises:
a fourth chopper coupled to between the third chopper and the operational amplifier; and
a fifth chopper coupled to the operational amplifier to receive the compensation signal.

9. The frequency locked loop circuit of claim 8, wherein the compensation node comprises a first compensation node and a second compensation node to receive a first compensation signal and a second compensation signal of the compensation signal, and the ripple reduction loop circuit further comprises:
a filter circuit coupled to two output terminals of the fifth chopper, and configured to generate the first compensation signal and the second compensation signal, wherein a voltage difference is between the first compensation signal and the second compensation signal.

10. The frequency locked loop circuit of claim 9, wherein the operational transconductance amplifier further comprises two compensation transistors, the two compensation transistors are respectively connected in parallel with two current mirror transistors in the current mirror circuit, and a plurality of control terminals of the two compensation transistors receive the first compensation signal and the second compensation signal.

11. The frequency locked loop circuit of claim 10, wherein the signal generation circuit comprises a first input node and a second input node, the first input node is coupled to a first current source, the second input node is coupled to a second current source, and the ripple reduction loop circuit further comprises:
a first impedance circuit coupled to the first input node; and
a second impedance circuit is coupled to the second input node, wherein the second impedance circuit is configured to adjust an impedance value of the second impedance circuit according to the reference clock signal.

12. The frequency locked loop circuit of claim 11, further comprising:
a switching circuit coupled to the first current source, the second current source, the first input node and the second input node, wherein the switching circuit is configured to periodically connect the first current source to one of the first input node and the second input node, and is configured to periodically connect the second current source to the other one of the first input node and the second input node.

13. The frequency locked loop circuit of claim 12, wherein the second impedance circuit comprises a switching element and a capacitor, the switching element is coupled to the capacitor and is configured to turn on or off according to the reference clock signal.

14. A phase locked loop system, comprising:
a signal generation circuit comprising:
a first chopper;
an operational transconductance amplifier coupled to the first chopper to receive a differential input signal;
a second chopper coupled to the operational transconductance amplifier, wherein the differential input signal is processed into an output signal at an output node by the operational transconductance amplifier and the second chopper; and
a ripple reduction loop circuit coupled to the output node to receive the output signal, and comprising a third chopper and an operational amplifier, wherein the third chopper is configured to convert a ripple in the output signal into a direct current offset signal, and the operational amplifier is configured to convert the direct current offset signal into a compensation signal to compensate for an offset voltage in the operational transconductance amplifier; and
a voltage controlled oscillator coupled to the signal generation circuit, and configured to generate a reference clock signal according to the output signal; and
a phase locked loop circuit coupled to the voltage controlled oscillator to receive the reference clock signal, and configured to output a output clock signal, wherein the phase locked loop circuit is configured to generate a feedback signal according to the output clock signal to adjust a phase of the output clock signal.

15. The phase locked loop system of claim 14, wherein the operational transconductance amplifier comprises a current mirror circuit and an amplifier circuit, the differential input signal is processed into the output signal at the output node by the current mirror circuit, the amplifier circuit and the second chopper, and the compensation signal is configured to input to a compensation node of the current mirror circuit.

16. The phase locked loop system of claim 15, wherein the ripple reduction loop circuit further comprises:
a fourth chopper coupled to between the third chopper and the operational amplifier; and
a fifth chopper coupled to the operational amplifier to receive the compensation signal.

17. The phase locked loop system of claim 16, wherein the compensation node comprises a first compensation node and a second compensation node to receive a first compensation signal and a second compensation signal of the compensation signal, and the ripple reduction loop circuit further comprises:
a filter circuit coupled to two output terminals of the fifth chopper, and configured to generate the first compensation signal and the second compensation signal, wherein a voltage difference is between the first compensation signal and the second compensation signal.

18. The phase locked loop system of claim 17, wherein the operational transconductance amplifier further comprises two compensation transistors, the two compensation transistors are respectively connected in parallel with two current mirror transistors in the current mirror circuit, and a plurality of control terminals of the two compensation transistors receive the first compensation signal and the second compensation signal.

19. The phase locked loop system of claim 14, wherein the signal generation circuit comprises a first input node and a second input node, the first input node is coupled to a first current source, the second input node is coupled to a second current source, and the signal generation circuit further comprises:
a first impedance circuit coupled to the first input node; and
a second impedance circuit is coupled to the second input node, wherein the second impedance circuit is configured to adjust an impedance value of the second impedance circuit according to the reference clock signal.

20. The phase locked loop system of claim 19, further comprising:
a switching circuit coupled to the first current source, the second current source, the first input node and the second input node, wherein the switching circuit is configured to periodically connect the first current source to one of the first input node and the second input node, and is configured to periodically connect the second current source to the other one of the first input node and the second input node.
